(19) United States
(12) Patent Application Publication
(10) Pub. No.: US 2026/0182298 A1
(43) Pub. Date: Jun. 25, 2026

(54) TRANSFER MODULE AND SUBSTRATE PROCESSING APPARATUS INCLUDING THE SAME

(71) Applicant: SEMES CO., LTD., Cheonan-si (KR)

(72) Inventors: Sang Bok HAN, Asan-si (KR); Sung Yong LEE, Yongin-si (KR)

(21) Appl. No.: 19/339,494

(22) Filed: Sep. 25, 2025

(30) Foreign Application Priority Data
Dec. 20, 2024 (KR) 10-2024-0192571

(51) Int. Cl. H01L 21/67; H01L 21/677; H01L 21/683

(52) U.S. Cl. CPC H10P 72/0616; H10P 72/3302; H10P 72/0414; H10P 72/78

(57) ABSTRACT

A transfer module includes a hand body supporting and handling a substrate, a detection unit including a light emitting portion disposed on a first side of the hand body and emitting light in one direction and a light receiving portion disposed on a second side of the hand body and receiving the light and detecting warpage of the substrate, and a controller determining a warpage state of the substrate based on a detection result of the warpage.

### CROSS-REFERENCE TO RELATED APPLICATIONS

This application claims benefit of priority to Korean Patent Application No. 10-2024-0192571 filed on Dec. 20, 2024 in the Korean Intellectual Property Office, the disclosure of which is incorporated herein by reference in its entirety.

### BACKGROUND

### 1. Field

The present disclosure relates to a transfer module and a substrate processing apparatus including the same.

### 2. Description of Related Art

To manufacture semiconductor devices, a predetermined pattern has to be formed on substrate, such as a wafer. Forming a predetermined pattern on a substrate may include sequential processes, such as a deposition process, a lithography process, and an etching process.

Among the above processes, when the lithography process is performed, the substrate may be heat-treated in a baking chamber. However, a substrate with a liquid film formed in a preceding process of a baking process may warp away from the center thereof, resulting in warpage. Warpage may have various forms, such as a substrate W having the center warped downwardly or upwardly, or a combination of both.

Due to the warpage phenomenon, the substrate may not fully contact an upper surface of a robot hand during transport, or when the substrate is mounted on a heating plate or spin head, a portion of the substrate, specifically a warped portion, may not fully contact an upper surface of the heating plate or spin head and but separated. As a result, the entire substrate may not be heated uniformly and a processing liquid spray nozzle may collide with a warped portion of the substrate during an edge bead removing (EBR) process.

To prevent these problems, a process of detecting substrate warpage is performed, which, however, not only increases the process time but also requires additional space for a detection device.

### RELATED ART DOCUMENT

### Patent Document

(Patent Document 1) Korean Application Publication No. 10-2024-0033877 (Mar. 13, 2024)

### SUMMARY

An aspect of the present disclosure is to provide a transfer module including a detection unit installed thereon to perform detection during transporting of a substrate to detect warpage of the substrate, thereby shortening the processing time, and a substrate processing apparatus not requiring an additional installation space for the detection unit, thereby improving space efficiency within the substrate processing apparatus.

According to an aspect of the present disclosure, a transfer module includes: a hand body supporting and handling a substrate; a detection unit including a light emitting portion disposed on a first side of the hand body and emitting light in one direction and a light receiving portion disposed on a second side of the hand body and receiving the light and detecting warpage of the substrate; and a controller determining a warpage state of the substrate based on a detection result of the warpage

According to another aspect of the present disclosure, a substrate processing apparatus includes: a transfer module including a hand body supporting and handling a substrate and a detection unit including a light emitting portion disposed on a first side of the hand body and emitting light in one direction and a light receiving portion disposed on a second side of the hand body and receiving the light and detecting warpage of the substrate; an adsorption module disposed on the hand body and including a plurality of adsorption portions adsorbing and fixing a bottom surface of the substrate; and a controller determining a warpage state of the substrate based on a detection result of the warpage and controlling the adsorption module.

According to another aspect of the present disclosure, a substrate processing apparatus includes: a processing chamber having a processing space provided therein; a transfer module including a hand body disposed on one side of the processing chamber to transfer a substrate to the processing space and supporting and handling the substrate and a detection unit including a light emitting portion disposed on a first side of the hand body and emitting light in one direction and a light receiving portion disposed on a second side of the hand body and receiving the light, wherein the light emitting portion and the light receiving portion are disposed opposite to each other in the one direction with the substrate supported on the hand body interposed therebetween and the detection unit detects a warpage of the substrate; an adsorption module disposed on the hand body and including a plurality of adsorption portions adsorbing and fixing a bottom surface of the substrate; and a controller determining a warpage state of the substrate based on a detection result of the warpage and controlling the adsorption module, wherein the light receiving portion includes a light receiving region in which the light is incident, the light receiving region is divided into a plurality of regions, including a first region disposed above the substrate supported by the hand body and a second region disposed below the substrate, based on the substrate, and the controller determines a warpage state including a direction and degree of bending of the substrate by comparing an amount of incident light detected in the first region with a first reference value and comparing an amount of incident light detected in the second region with a second reference value, the controller determines that the substrate is at least partially bended upward when the amount of incident light detected in the first region is less than the first reference value and determines that the substrate is at least partially bended downward if the amount of incident light detected in the second region is less than the second reference value, and the controller determines that the degree of the upward or downward bending of the substrate is greater as a detection value of the amount of incident light in the first region and a detection value of the amount of incident light in the second region decrease.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a top view of a substrate processing apparatus according to an embodiment of the present disclosure;

FIG. 2 is a view of the substrate processing apparatus of FIG. 1, as viewed in the A-A direction;

FIG. 3 is a view of the substrate processing apparatus of FIG. 1, as viewed in the B-B direction;

FIG. 4 is a perspective view illustrating a transfer module according to an embodiment of the present disclosure;

FIG. 5 is a perspective view illustrating a portion of a transfer module according to an embodiment of the present disclosure;

FIG. 6 is a cross-sectional view schematically illustrating an example of a transfer module and a substrate supported thereon, as viewed in direction I-I′ in FIG. 5;

FIG. 7 is a cross-sectional view schematically illustrating another example of a transfer module and a substrate supported thereon, as viewed in direction I-I′ in FIG. 5;

FIG. 8 is a cross-sectional view schematically illustrating another example of a transfer module and a substrate supported thereon, as viewed in direction I-I′ in FIG. 5;

FIG. 9 is a cross-sectional view schematically illustrating an example of a transfer module adsorbing and securing a substrate, as viewed in direction I-I′ in FIG. 5;

FIG. 10 is a cross-sectional view schematically illustrating another example of a transfer module adsorbing and securing a substrate, as viewed in direction I-I′ in FIG. 5;

FIG. 11 is a cross-sectional view schematically illustrating an example of processing an edge portion of a substrate supported on a transfer module as viewed in direction I-I′ in FIG. 5;

FIG. 12 is a cross-sectional view schematically illustrating another example of processing an edge portion of a substrate supported on a transfer module as viewed in direction I-I′ in FIG. 5; and

FIG. 13 is a cross-sectional view schematically illustrating another example of processing an edge portion of a substrate supported on a transfer module as viewed in direction I-I′ in FIG. 5.

### DETAILED DESCRIPTION

Hereinafter, embodiments will be described in detail with reference to the accompanying drawings such that they may be easily practiced by those skilled in the art to which the present disclosure pertains. In describing the present disclosure, if a detailed explanation for a related known function or construction is considered to unnecessarily divert the gist of the present disclosure, such explanation will be omitted but would be understood by those skilled in the art. Also, similar reference numerals are used for the similar parts throughout the specification. In this disclosure, terms, such as “above,” “upper portion,” “upper end,” “below,” “lower portion,” “lower end,” and the like, are determined based on the drawings, and in actuality, the terms may be changed according to a direction in which a device or an element is disposed.

In addition, unless explicitly described to the contrary, the word “comprise” and variations, such as “comprises” or “comprising,” will be understood to imply the inclusion of stated elements but not the exclusion of any other elements.

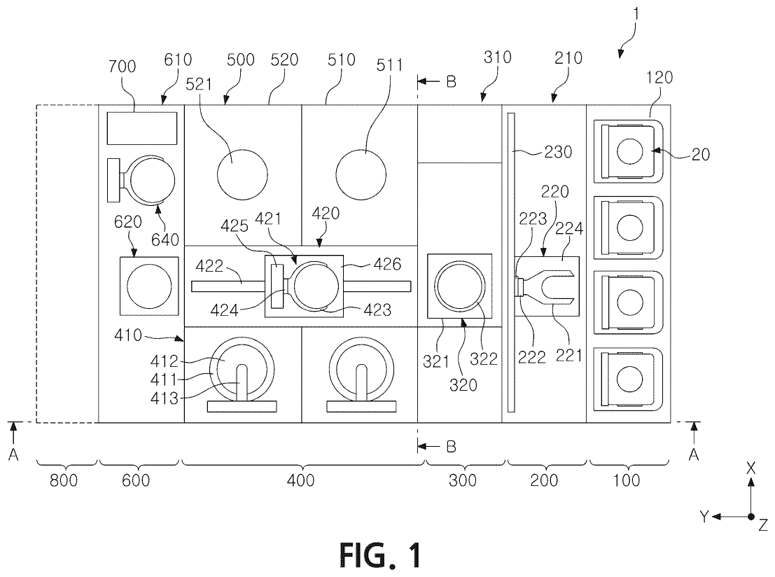

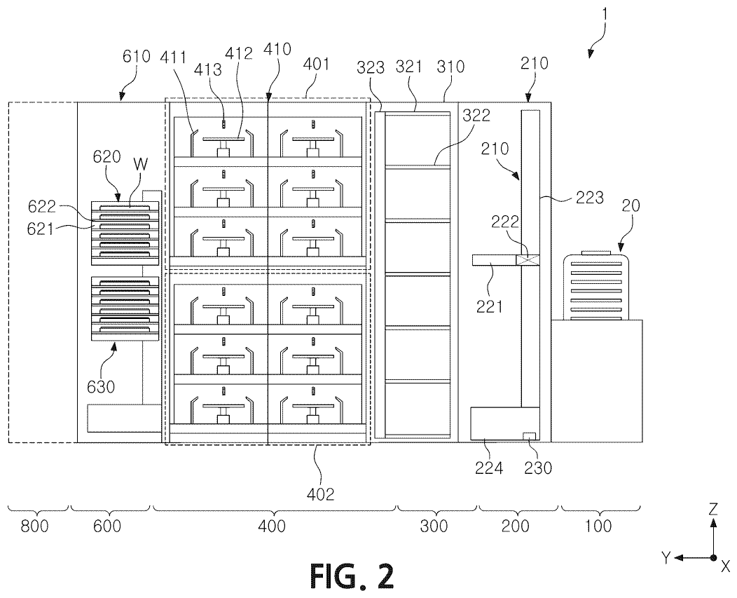

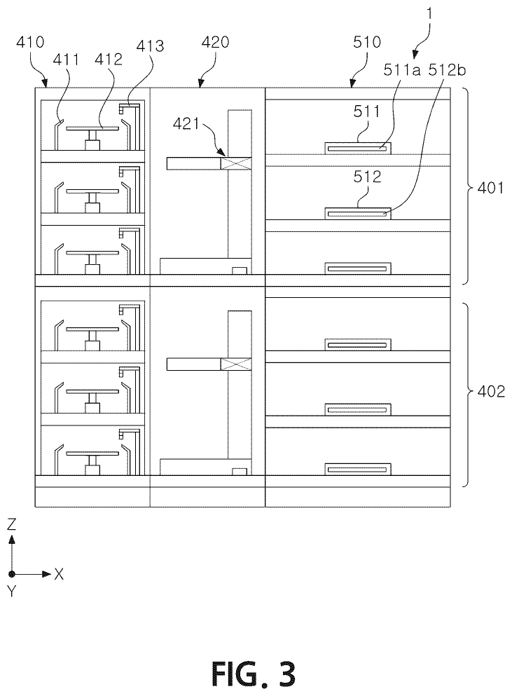

FIG. 1 is a top view of the substrate processing apparatus, FIG. 2 is a view of the substrate processing apparatus of FIG. 1, as viewed in the A-A direction, and FIG. 3 is a view of the substrate processing apparatus of FIG. 1, as viewed in the B-B direction.

Referring to FIGS. 1 to 3, a substrate processing apparatus 1 may include a load port 100, an index module 200, a buffer module 300, an application and development module 400, and a purge module 700. The load port 100, the index module 200, the buffer module 300, the application and development module 400, and an interface module 600 may be sequentially arranged in a row in one direction. The purge module 700 may be provided within the interface module 600. Alternatively, the purge module 700 may be provided in various locations, such as at a location at the rear of the interface module 600 to which an exposure device 800 is connected or on the side of the interface module 600. Hereinafter, a direction in which the load port 100, the index module 200, the buffer module 300, the application and development module 400, and the interface module 600 are arranged is referred to as a first direction Y, a direction, perpendicular to the first direction Y when viewed from above, is referred to as a second direction X, and a direction, perpendicular to both the first direction Y and the second direction X is referred to as a third direction Z.

A substrate W may be moved while received within a cassette 20. The cassette 20 may have a structure that may be sealed from the outside. For example, a front open unified pod (FOUP) with a door at the front may be used as the cassette 20.

Hereinafter, the load port 100, the index module 200, the buffer module 300, the application and development module 400, the interface module 600, and the purge module 700 are described in detail.

The load port 100 may have a mounting plate 120 on which the cassette 20 in which the substrate W is received is placed. The mounting plate 120 may be provided in plural, and the plurality of mounting plates 120 may be disposed in a row in the second direction X. Although FIG. 1 illustrates an example in which four mounting plates 120 are provided, the number of the mounting plates 120 may vary.

The index module 200 may transport the substrate W between the cassette 20 placed on the mounting plate 120 of the load port 100 and the buffer module 300. The index module 200 may include a frame 210, an index robot 220, and a guide rail 230.

The frame 210 may be generally provided in the shape of a hollow rectangular parallelepiped and may be disposed between the load port 100 and the buffer module 300. The frame 210 of the index module 200 may be provided at a lower height than that of the frame 310 of the buffer module 300.

The index robot 220 and the guide rail 230 may be disposed within the frame 210. The index robot 220 may be provided such that a hand 221 directly handling the substrate W may move and rotate in the first direction Y, the second direction X, and the third direction Z. The index robot 220 may include the hand 221, an arm 222, a support 223, and a pedestal 224. The hand 221 may be fixedly installed to the arm 222. The arm 222 may be provided with a retractable structure and a rotatable structure. The support 223 may be disposed in the third direction Z as a length direction thereof. The arm 222 may be coupled to the support 223 so as to be movable along the support 223. The support 223 may be fixedly coupled to the pedestal 224. The guide rail 230 may be provided in the second direction X as a length direction thereof. The pedestal 224 may be coupled to the guide rail 230 so as to be movable linearly along the guide rail 230. In addition, although not shown, the frame 210 may further be provided with a door opener for opening and closing the door of the cassette 20.

The buffer module 300 may include a frame 310, a first buffer 320, a second buffer 330, and a cooling chamber 340. The frame 310 may be provided in the shape of a hollow rectangular parallelepiped and may be disposed between the index module 200 and the application and development module 400. The first buffer 320, the second buffer 330, and the cooling chamber 340 may be disposed within the frame 310. The cooling chamber 340, the second buffer 330, and the first buffer 320 may be sequentially arranged from below in the third direction Z. The first buffer 320 may be disposed at a height corresponding to an application module 401 of the application and development module 400, and the second buffer 330 and the cooling chamber 340 may be provided at a height corresponding to a development module 402 of the application and development module 400.

The first buffer 320 and the second buffer 330 may each temporarily store a plurality of substrates W. The first buffer 320 may have a housing 321 and a plurality of supports 322. In the first buffer 320, the supports 322 may be disposed within the housing 321 and spaced apart from each other in the third direction Z. The second buffer 330 may have a housing 331 and a plurality of supports 332. In the second buffer 330, the supports 332 may be disposed within the housing 331 and spaced apart from each other in the third direction Z. One substrate W may be placed on each support 322 of the first buffer 320 and each support 332 of the second buffer 330. The housing 331 may have an opening in a direction in which the index robot 220 is provided so that the index robot 220 may load or unload the substrate W to or from the support 332 within the housing 331.

The first buffer 320 has a structure generally similar to that of the second buffer 330. However, the housing 321 of the first buffer 320 may have an opening in a direction in which the first buffer robot 360 is provided and in a direction in which the application robot 421 disposed in the application module 401 is provided. The number of supports 322 provided in the first buffer 320 and the number of supports 332 provided in the second buffer 330 may be the same or different. In an example, the number of supports 332 provided in the second buffer 330 may be greater than the number of supports 322 provided in the first buffer 320.

Each cooling chamber 340 may cool the substrate W. The cooling chamber 340 may include a housing 341 and a cooling plate 342. The cooling plate 342 may have an upper surface on which the substrate W is placed and a cooling unit 343 cooling the substrate W. Various cooling methods, such as cooling using coolant or a thermoelectric element, may be used as the cooling unit 343. Furthermore, the cooling chamber 340 may be provided with a lift pin assembly for positioning the substrate W on the cooling plate 342. The housing 341 may have an opening in a direction in which the index robot 220 is provided and in a direction in which a development robot is provided, so that the development robot provided in the index robot 220 and the development module 402 may load or unload the substrate W onto or from the cooling plate 342. Furthermore, the cooling chamber 340 may be provided with doors for opening and closing the opening described above.

In the above, although the embodiment in which the buffer module 300 includes the cooling chamber 340 is described, the present disclosure is not limited thereto, and the cooling chamber 340 may be omitted as needed.

The application module 401 may include a process of applying a photosensitive solution, such as photoresist, to the substrate W, and a heat treatment process, such as heating and cooling, on the substrate W before and after a resist application process. The application module 401 may include an application chamber 410, a heat treatment chamber unit 500, and a transfer chamber 420. The application chamber 410, the transfer chamber 420, and the heat treatment chamber unit 500 may be sequentially arranged in the second direction X. That is, with respect to the transfer chamber 420, the application chamber 410 may be provided on one side of the transfer chamber 420, and the heat treatment chamber unit 500 may be provided on the other side of the transfer chamber 420.

The application chamber 410 may be provided in plural, and the plurality of application chambers 410 may each be provided in the third direction Z. Furthermore, as illustrated in FIG. 1, a plurality of application chambers 410 may be provided in the first direction Y, or a single application chamber 410 may be provided in the first direction Y.

The heat treatment chamber unit 500 may include a baking chamber 510 and a cooling chamber 520, and a plurality of baking chambers 510 and a plurality of cooling chambers 520 may be provided in the third direction Z. The transfer chamber 420 may be disposed parallel to the first buffer 320 of the first buffer module 300 in the first direction Y. An application robot 421 and a guide rail 422 may be disposed within the transfer chamber 420. The transfer chamber 420 may have a generally rectangular shape. The application robot 421 may transport the substrate W between the baking chamber 510, the cooling chamber 520, the application chamber 410, and the first buffer 320 of the first buffer module 300.

The guide rail 422 may be disposed such that a length direction thereof is parallel to the first direction Y. The guide rail 422 may guide the application robot 421 to move linearly in the first direction Y. The application robot 421 may have a hand 423, an arm 424, a support 425, and a pedestal 426. The hand 423 may be fixedly installed on the arm 424. The arm 424 may be provided with a stretchable structure so that the hand 423 may move in a horizontal direction. The support 425 may be provided in the third direction Z as a length direction thereof. The arm 424 may be coupled to the support 425 so as to be linearly movable along the support 425 in the third direction Z. The support 425 may be fixedly coupled to the pedestal 426, and the pedestal 426 may be coupled to the guide rail 422 so as to be movable along the guide rail 422.

The application chambers 410 may all have the same structure, but the type of processing liquid used in each application chamber 410 may differ. Processing liquids used for forming photoresist films or anti-reflective films may be used.

The application chamber 410 may apply the processing liquid onto the substrate W. The application chamber 410 may be provided with a processing unit including a processing container 411, a support portion 412, and a nozzle portion 413.

For example, the application chamber 410 may each have a single processing unit disposed in the first direction Y. However, without being limited thereto, two or more processing units may be disposed in the single application chamber 410. Each processing unit may have the same structure. However, the type of processing liquid used in each processing unit may differ. The processing container 411 of the application chamber 410 may have an open top. The support portion 412 is disposed within the processing container 411 and may support the substrate W. The support portion 412 may be provided to be rotatable. The nozzle portion 413 may supply a processing liquid onto the substrate W placed on the support portion 412. The processing liquid may be applied to the substrate W using a spin coating method. In addition, the application chamber 410 may optionally be further provided with a nozzle (not shown) for supplying a cleaning solution, such as deionized water (DIW), to clean the surface of the substrate W to which the processing liquid has been applied and a back rinse nozzle (not shown) for cleaning a lower surface of the substrate W.

In the baking chamber 510, the substrate W may be heat-treated once the substrate W is mounted thereon by the application robot 421. In the baking chamber 510, a prebaking process of heating the substrate W to a predetermined temperature before applying the processing liquid to remove organic substances or moisture from the surface of the substrate W or a soft baking process to be performed after applying the processing liquid onto the wafer W may be performed. A cooling process of cooling the substrate W may be performed after each heating process.

The baking chamber 510 may be provided with a heating plate 511 and a heating unit 511a.

The heating unit 511a may heat the substrate W placed inside the baking chamber 510. Here, the substrate W is heated while the baking chamber 510 is sealed, and the heating unit 511a may uniformly heat the entire region of the substrate W. For example, the heating unit 511a may use a heating method using heating wires provided on the internal or external surface of the heating plate 511. In addition, a heating method using a device, such as a heater placed inside or outside the baking chamber 510, may be used. The heat treatment process may evaporate organic substances from a liquid film formed by applying the processing liquid to the substrate W, thereby stabilizing the liquid film.

Furthermore, the baking chamber 510 may further be provided with a cooling plate (or a chill plate) (not shown). The cooling plate may receive coolant from the cooling unit 910, to be described below, to cool the substrate W. Accordingly, the substrate W may be prevented from being heated to excessively high temperatures during the heat treatment process. The substrate W, on which the heat treatment process is completed, may be transported to the cooling chamber 520.

The cooling chamber 520 performs a cooling process to cool the substrate W before applying the processing liquid. The cooling chamber 520 may be provided with a cooling plate. The cooling plate may include a cooling unit that may use various methods, such as cooling with coolant or cooling using a thermoelectric element, to cool the substrate W.

The interface module 600 may connect the application and development module 400 to an external exposure device 800. The interface module 600 may include an interface frame 610, a first interface buffer 620, a second interface buffer 630, and a transfer robot 640. The transfer robot 640 may transfer the substrate transferred to the first and second interface buffers 620 and 630 after the application and development module 400 has completed its work to the exposure device 800. The first and second interface buffers 620 may include a housing 621 and a support 622, and the transfer robot 640 and the application robot 421 may load and unload the substrate W onto and from the support 622.

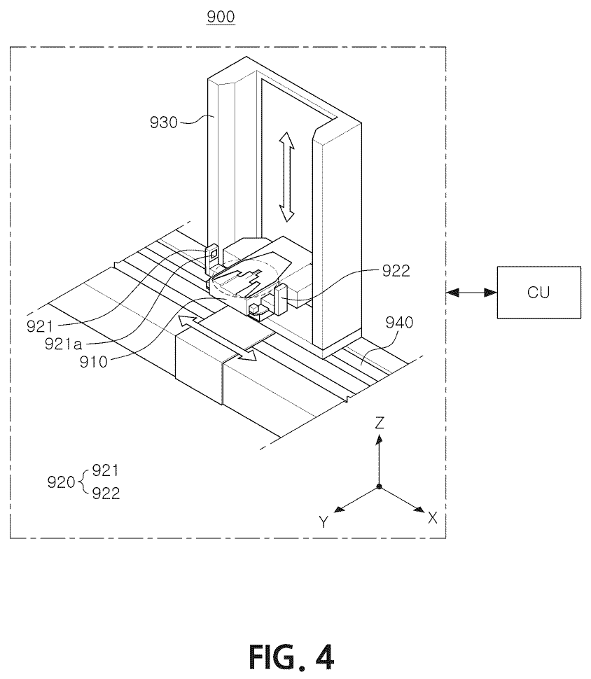

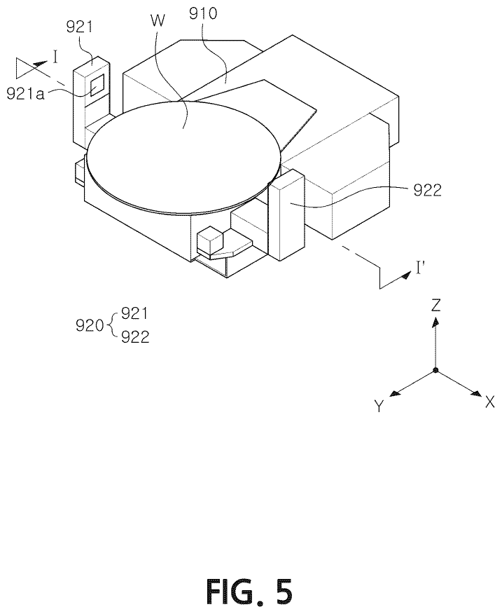

FIG. 4 is a perspective view illustrating a transfer module according to an embodiment of the present disclosure. FIG. 5 is a perspective view illustrating a portion of a transfer module according to an embodiment of the present disclosure.

Referring to FIGS. 4 and 5, a transfer module 900 may be a device for transporting the substrate W within the substrate processing apparatus 1. For example, the transfer module 900 may transfer the substrate W between a plurality of processing chambers provided in the substrate processing apparatus 1. Furthermore, the transfer module 900 may transport the substrate to a processing space provided within the processing chamber. Here, the processing chamber may be, but is not limited to, the application chamber 410 in which a processing liquid application process is performed on the substrate W, or the baking chamber 510 in which a baking process of heat-treating the substrate W is performed.

The transfer module 900 may be the aforementioned index robot 220. However, the present disclosure is not limited thereto. In another embodiment, the transfer module 900 may be a device provided separately from the index robot 220. In this case, the transfer module 900 may include a hand body 910 and a detection unit 920. Furthermore, the transfer module 900 may further include a first transfer unit 930, a second transfer unit 940, and a controller CU.

The hand body 910 may support the substrate W, while the substrate W is being transferred. The hand body 910 may be provided in various forms. For example, the hand body 910 may be a plate-shaped body on which the substrate W may be mounted and supported. In this case, the hand body 910 may be provided with a adsorption portion Ab for adsorbing and fixing the substrate W, which will be described below.

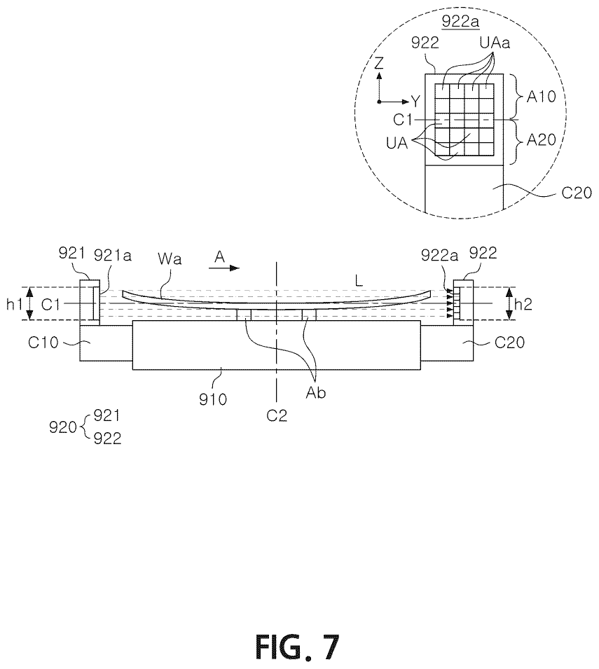

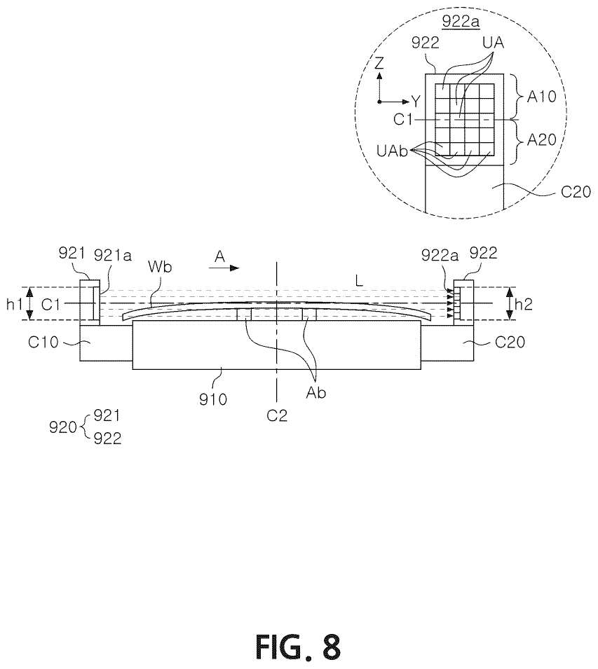

During the substrate processing process, a baking process, in which the substrate W is heat-treated, may be performed in the baking chamber 510. However, the substrate W on which the liquid film has been formed in the preceding stage of the baking process, may develop warpage, that is, the substrate is bended in a direction away from the center. For example, the warpage may be formed in a shape in which a central portion C2 of the substrate W is bended downward (hereinafter, referred to as a first shape) (see Wa in FIG. 7) or in a shape in which the central portion C2 of the substrate W is bended upward (hereinafter, referred to as a second shape) (see Wb in FIG. 8). Alternatively, the warpage may have various shapes (not shown), such as a combination of the first and second shapes described above.

The detection unit 920 may detect the warpage of the substrate W as described above. More specifically, the detection unit 920 may detect whether warpage has occurred on the substrate W and the shape of the warpage occurring on the substrate W. The detection unit 920 may be, for example, a linear CCD or a displacement sensor.

The detection unit 920 may include a light emitting portion 921 and a light receiving portion 922. The light emitting portion 921 may be disposed on one side (hereinafter, referred to as a first side) of the hand body 910. The light receiving portion 922 may be disposed on the other side (hereinafter, referred to as a second side) of the hand body 910. For example, the light emitting portion 921 may be connected to the first side of the hand body 910 by a first connection member C10, and the light receiving portion 922 may be connected to the second side of the hand body 910 by a second connection member C20. In this case, the first and second sides of the hand body 910 may be disposed opposite to each other in one direction. Accordingly, the light emitting portion 921 and the light receiving portion 922 may be disposed to face each other in one direction.

The light emitting portion 921 may include a light source 921a. The light source 921a is a unit emitting light L and may emit light L in one direction as described above. Here, the one direction may be a direction, parallel to a radial direction of the substrate W supported on the hand body 910 and may be a direction in which the light L emitted from the light emitting portion 921 travels. Hereinafter, the one direction is referred to as a “traveling direction (A).” The light L emitted from the light emitting portion 921 may travel toward the light receiving portion 922 along the traveling direction (A). The light L irradiated to the light receiving portion 922 may be received by a light receiving region 922a of the light receiving portion 922.

When the substrate W is supported on the hand body 910, the substrate W may be disposed between the light emitting portion 921 and the light receiving portion 922, which face each other as described above. Accordingly, light L emitted from the light emitting portion 921 may pass through the substrate W and be irradiated to the light receiving portion 922. The light receiving portion 922 may include a light detection sensor (not shown). The light detection sensor may be disposed in the light receiving region 922a to detect the amount of incident light L irradiated to the light detection sensor. In this case, the amount of light (amount of incident light) incident on the light receiving region 922a may vary depending on the warpage shape of the substrate W, as will be described below.

The first transfer unit 930 may elevate the hand body 910 in a vertical Z direction. For example, the first transfer unit 930 may include a pair of supports extending parallel in the vertical direction Z. In this case, the hand body 910 may be connected between the pair of supports and may be raised or lowered in the vertical direction Z. To this end, the first transfer unit 930 may include a first driving unit (not shown). The first driving unit may be driven in various manners, such as by an electric motor or a hydraulic cylinder.

The second transfer unit 940 may make the hand body 910 reciprocate in a horizontal direction (e.g., in the X-axis direction). For example, the second transfer unit 940 may be provided in the form of a guide rail. In this case, a lower end portion of the first transfer unit 930 may be coupled to the second transfer unit 940. The first transfer unit 930 may reciprocate in an extension direction X of the second transfer unit 940, and accordingly, the hand body 910 coupled to the first transfer unit 930 may also reciprocate. Here, the second transfer unit 940 may transfer the hand body 910 between adjacent processing chambers. To this end, the second transfer unit 940 may include a second driving unit (not shown). Like the first driving unit, the second driving unit may be driven in various manners, such as by an electric motor or a hydraulic cylinder.

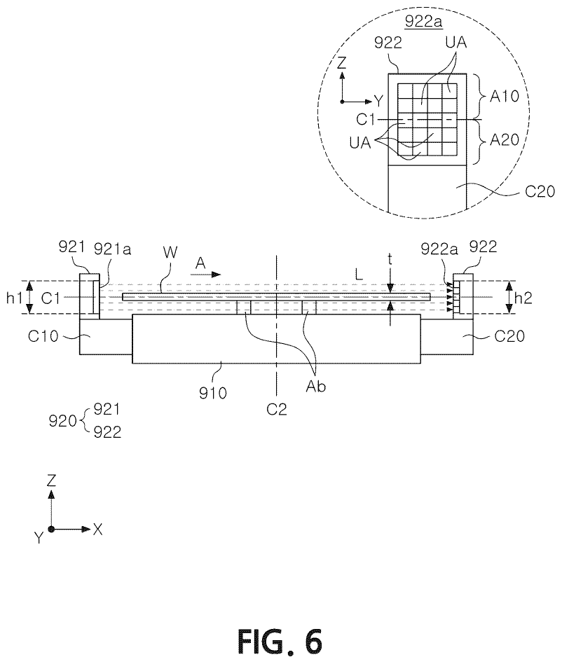

FIG. 6 is a cross-sectional view schematically illustrating an example of a transfer module and a substrate supported thereon, as viewed in direction I-I′ in FIG. 5. FIG. 7 is a cross-sectional view schematically illustrating another example of a transfer module and a substrate supported thereon, as viewed in direction I-I′ in FIG. 5. FIG. 8 is a cross-sectional view schematically illustrating another example of a transfer module and a substrate supported thereon, as viewed in direction I-I′ in FIG. 5. Here, the enlarged views shown in the upper right of FIGS. 6 through 8 illustrate the light receiving portion 922 as viewed from the front (e.g., a Y-Z plane direction).

Referring to FIG. 6, the controller CU may determine a warpage state of the substrate W based on warpage detection result of the substrate W. The controller CU may be implemented, for example, in the form of a circuit board mounted on a control computer of the substrate processing apparatus 1, a computer chip mounted on the circuit board, or software embedded in the computer chip or the control computer. Here, when light L reaches the light receiving region 922a, the controller CU may detect the warpage state of the substrate W based on the amount of incident light detected by the light detection sensor.

The light receiving portion 922 may be provided in a form in which the light receiving region 922a is divided into a plurality of regions. A light detection sensor may be disposed in each of the divided regions. In this case, the controller CU may receive the detection results of each light detection sensor and determine the warpage state of the substrate W based on the amount of incident light of each region.

The light receiving region 922a may be divided into a first region A10 and a second region A20. The first region A10 and the second region A20 may be determined based on the position of the substrate W. That is, the first region A10 may be located above the substrate W disposed on the hand body 910. The second region A20 may be located below the substrate W disposed on the hand body 910.

In an embodiment, the first region A10 and the second region A20 may be further divided into a plurality of unit regions UA. In this case, the plurality of unit regions UA included in the first region A10 and the second region A20 may be arranged within the light receiving region 922a. For example, the plurality of unit regions UA may be arranged in a grid pattern within the light receiving region 922a. Each of the unit regions UA may be provided with the light detection sensor.

The light emitting portion 921 may be provided such that a height (hereinafter, referred to as a first height) h1 of the light source 921a is greater than a thickness t of the substrate W. Furthermore, the light receiving portion 922 may be provided such that the light receiving region 922a has a height (hereinafter, referred to as a second height) h2 greater than the thickness t of the substrate W. Accordingly, the region irradiated with light L from the light source 921a to the light receiving region 922a in the vertical direction Z may cover the entire thickness region of the substrate W. Furthermore, the first height h1 and the second height h2 may be provided to be sufficiently longer than the thickness t of the substrate W, so that the region irradiated with light L may cover the entire surface from the top to the bottom of the substrate W even if warpage occurs on the substrate W.

In the above case, the light L emitted from the light source 921a of the light emitting portion 921 may travel along the traveling direction (A) toward the light receiving region 922a. The light L may pass through the substrate W, while traveling from the region between the light emitting portion 921 and the light receiving portion 922 toward the light receiving region 922a. Here, the amount of light L passing through the region in which the substrate W is placed and reaching the light receiving region 922a may be less than the amount of light L passing through a region in which the substrate W is not placed and reaching the light receiving region 922a. This is because a portion of the light L passing through the in-between region encounters the substrate W and is blocked or reflected. This may result in a difference in the amount of incident light between the first region A10 and the second region A20 of the light receiving region 922a.

Using this difference in the amount of incident light, the controller CU may determine whether the substrate W is placed on the hand body 910. For example, after the same or similar amount of light L is emitted from all regions of the light source 921a, if the amount of incident light detected in a portion (e.g., the central region) of the light receiving region 922a is relatively small, the controller CU may determine that the substrate W is supported by the hand body 910. In another example, if the same or similar amount of incident light is detected in all unit regions of the light receiving region 922a, the controller CU may determine that the substrate W is not supported by the corresponding hand body 910.

When the substrate W is supported by the hand body 910, the controller CU may detect whether warpage has occurred in the substrate W.

As illustrated in FIG. 6, when warpage does not occur on the substrate W, the amount of incident light on the first region A10 and the amount of incident light on the second region A20 may be the same as or similar to each other. This is because the substrate W in which warpage does not occur is flat and is not bended upward (+Z) or downward (−Z), and thus does not block the traveling of light L to the first region A10 and/or the second region A20. In this manner, when the amount of incident light detected in the first region A10 and the second region A20 are the same or nearly similar, the controller CU may determine that warpage has not occurred on the substrate W.

Hereinafter, a substrate in which warpage has not occurred is defined as a “first substrate W.” When the first substrate W is being transferred by the transfer module 900, the amount of incident light detected by the detection unit 920 in the first region A10 is defined as a “first reference value,” and the amount of incident light detected in the second region A20 is defined as a “second reference value.” The first and second reference values may be used to determine a direction and degree of bending of the substrate W in which warpage has occurred, as described below.

Conversely, if there is a difference in the amounts of incident light detected in the first region A10 and the second region A20, the controller CU may determine that warpage has occurred on the corresponding substrate W.

For example, as illustrated in FIG. 7, when a ‘substrate (hereinafter defined as a second substrate) Wa in which warpage has occurred in the first form’ is transferred while being mounted on the hand body 910, light L emitted from the light emitting portion 921 may travel in the traveling direction (A) and be incident on the light receiving region 922a. Here, the traveling of light L may be at least partially blocked due to the upward (+Z) bended shape of the second substrate Wa. As a result, the amount of incident light detected in the first region A10 while the second substrate Wa is being transferred may be less than the ‘first reference value’, which is the amount of incident light detected in the first region A10 when the first substrate W is transferred.

That is, when the substrate transferred by the transfer module 900 is the second substrate Wa, the amount of incident light detected in the first region A10 may be less than the first reference value. In this case, the amount of incident light detected in the first region A10 may also be less than the amount of incident light detected in the second region A20. If the amount of incident light detected in the first region A10 is less than the first reference value, the controller CU may determine that warpage has occurred in the corresponding substrate (i.e., the second substrate) Wa in a shape (the first shape) that is warped upward (+Z).

In this case, the controller CU may determine the degree of bending of the second substrate Wa. More specifically, the controller CU may determine the degree of bending of the second substrate Wa in the upward (+Z) direction based on the difference in the amount of incident light between the plurality of unit regions UA included in the first region A10. For example, if the amount of incident light reaching a unit region (hereinafter, referred to as a first unit region) (e.g., UAa in FIG. 7) disposed at the upper (e.g., uppermost) end among the unit regions UA of the first region A10 is relatively small, the controller CU may determine that the degree of upward (+Z) bending of the second substrate Wa is more severe than a case in which the amount of incident light reaching the same first unit region UAa is relatively large.

As another example, as illustrated in FIG. 8, if a “substrate (hereinafter, referred to as a “third substrate”) Wb in which the warpage has occurred in the second form” is transferred while being mounted on the hand body 910, light L emitted from the light emitting portion 921 may travel in the traveling direction (A) and be incident on the light receiving region 922a. Here, due to the downward (−Z) bended shape of the third substrate Wb, the traveling of light L toward the second region A20 may be at least partially blocked. As a result, the amount of incident light detected in the second region A20 while the third substrate Wb is being transferred may be less than the “second reference value,” which is the amount of incident light detected in the second region A20 when the first substrate W is transferred.

That is, when the substrate transferred by the transfer module 900 is the third substrate Wb, the amount of incident light detected in the second region A20 may be less than the aforementioned second reference value. In this case, the amount of incident light detected in the second region A20 may also be less than the amount of incident light detected in the first region A10. When the amount of incident light in the second region A20 is detected to be less than the second reference value, the controller CU may determine that warpage has occurred in the corresponding substrate (i.e., the third substrate) Wb in a shape (the second shape) that is warped downward (−Z).

In this case, the controller CU may determine the degree of bending of the third substrate Wb. More specifically, the controller CU may determine the degree of downward (−Z) bending of the third substrate Wb based on the difference in the amount of incident light between the plurality of unit regions UA included in the second region A20. For example, if the amount of incident light reaching a unit region (hereinafter, referred to as a second unit region) (e.g., UAb in FIG. 8) disposed at the lower (e.g., the lowermost) end among the unit regions UA of the second region A20 is relatively small, the controller CU may determine that the degree of downward (−Z) bending of the third substrate Wb is more severe than a case in which the amount of incident light reaching the same second unit region UAb is relatively large.

The warpage detection of the substrates W, Wa, and Wb described above may be performed while the transfer module 900 transfers the substrate W. In this manner, by detecting the warpage during transfer, a separate time for warpage detection is not required, thereby reducing the process time for substrate processing. Furthermore, since the detection unit 920 is installed on the hand body 910 to detect warpage, there is no need to install a detection unit in a separate space, such as an upper portion of the hand body 910, thereby improving the space efficiency of the substrate processing apparatus 1.

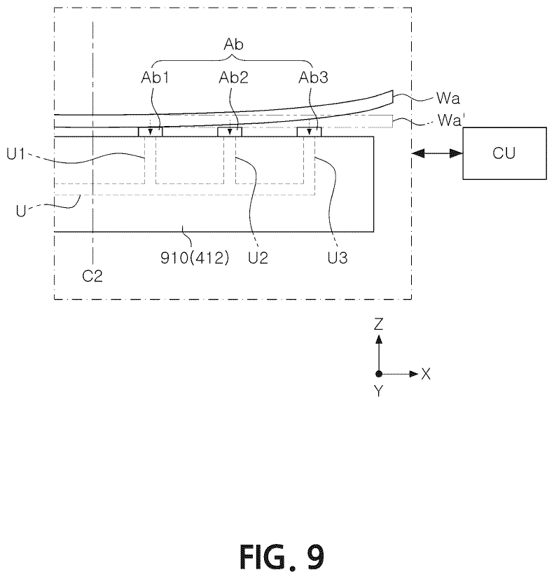

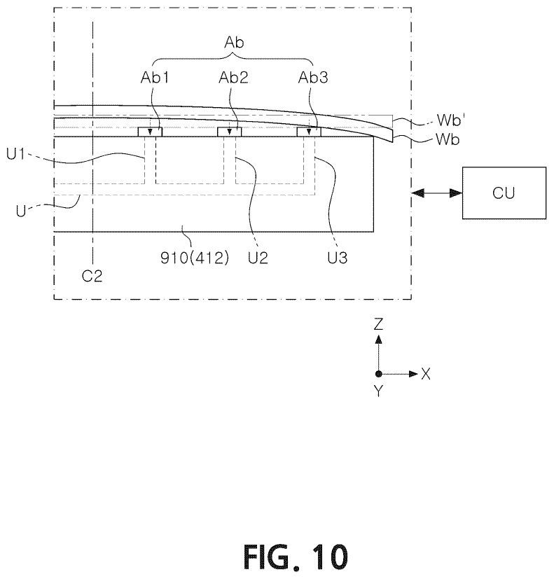

FIG. 9 is a cross-sectional view schematically illustrating an example of a transfer module adsorbing and securing a substrate, as viewed in direction I-I′ in FIG. 5. FIG. 10 is a cross-sectional view schematically illustrating another example of a transfer module adsorbing and securing a substrate, as viewed in direction I-I′ in FIG. 5.

Referring to FIGS. 9 and 10, the substrate processing apparatus 1 may further include an adsorption module. The adsorption module may fix the substrate W on the hand body 910 while the substrate W is transferred and/or while a processing process is in progress on the substrate W. Here, the adsorption module may include an adsorption portion Ab, a connection line U, and a adsorption force generating portion (not shown).

The adsorption portion Ab may be disposed on the hand body 910. More specifically, a plurality of adsorption portions Ab may be provided. The plurality of adsorption portions Ab1, Ab2, and Ab3 may be disposed on an upper surface of the hand body 910. The plurality of adsorption portions Ab1, Ab2, and Ab3 may be evenly distributed across the entire upper surface of the hand body 910.

The plurality of adsorption portions Ab1, Ab2, and Ab3 may be connected to the adsorption force generating portion via the connection line U. More specifically, the plurality of adsorption portions Ab1, Ab2, and Ab3 may be respectively connected to a plurality of branch lines U1, U2, and U3 branching from the connection line U. Here, the connection line U and branch lines U1, U2, and U3 may be provided to extend through the interior of the hand body 910. The connection line U may be connected to the adsorption force generation unit disposed outside the hand body 910.

The adsorption force generation unit may generate vacuum pressure to vacuum-adsorb a bottom surface of the substrate W using a vacuum pump (not shown). The vacuum pressure generated by the vacuum pump may be supplied to each of the adsorption portions Ab1, Ab2, and Ab3 through the connection line U and branch lines U1, U2, and U3. Accordingly, when the substrate W is mounted on the hand body 910, the bottom surface of the substrate W may be vacuum-absorbed and secured to the adsorption portion Ab.

In the above case, the controller CU may control the adsorption module based on the warpage detection result of the substrate W as described above. More specifically, the controller CU may control the adsorption module so that a stronger adsorption force is provided to a portion of the substrate W with a greater degree of bending using the warpage detection result.

For example, as illustrated in FIG. 9, based on the warpage detection result by the detection unit 920, the controller CU may determine that the substrate being transferred is the second substrate Wa that has developed warpage in the first form. In this case, the second substrate Wa may have a form in which the degree of upward (+Z) bending increases radially outward from the center C2. Due to the shape of bending of the second substrate Wa and the difference in the degree of bending in the radial direction, the distance between the bottom surface of the second substrate Wa and the hand body 910 may increase radially outward from the center C2.

In this case, the controller CU may control the adsorption portions Ab disposed further outward in the radial direction of the substrate to provide a stronger adsorption force than that of the adsorption portions disposed radially inward. For example, when the second substrate Wa is being transferred, the controller CU may control the adsorption force to gradually increase from the first adsorption portion Ab1 closest to the center C2 of the second substrate Wa toward the adsorption portions Ab2 and Ab3 arranged radially outward. That is, the first adsorption portion Ab1 provides the weakest adsorption force to the bottom surface of the second substrate Wa, followed by the second adsorption portion Ab2, and then the third adsorption portion Ab3. Accordingly, the “adsorption portion located below the portion with greater warpage [e.g., the third adsorption portion Ab3]” of the second substrate Wa may adsorb the bottom surface of the second substrate Wa with a stronger adsorption force than those of the “adsorption portion located below the portion with less warpage [e.g., the first adsorption portion Ab1 or the second adsorption portion Ab2]” in the second substrate Wa.

As another example, as illustrated in FIG. 10, based on the warpage detection result by the detection unit 920, the controller CU may determine that the substrate being transferred is the third substrate Wb that has developed warpage in the second form. In this case, the third substrate Wb may have a shape in which the degree of downward (−Z) bending becomes more severe radially outward from the center C2. Due to the bended shape of the third substrate Wb and the difference in the degree of bending in the radial direction, the distance between the bottom surface of the third substrate Wb and the hand body 910 may increase from the edge portion toward the center C2 in the radial direction.

In the above case, the controller CU may control the adsorption portions Ab disposed further inward in the radial direction of the substrate, among the plurality of adsorption portions Ab, to provide stronger adsorption force than those of the adsorption portions disposed further outward in the radial direction. For example, when the third substrate Wb is being transferred, the controller CU may control the adsorption force to gradually increase from the third adsorption portion Ab3 farthest from the center C2 of the third substrate Wb toward the adsorption portions Ab2 and Ab1 disposed inward in the radial direction. That is, the third adsorption portion Ab3 may provide the weakest adsorption force to the bottom surface of the third substrate Wb, followed by the second adsorption portion Ab2, and then the first adsorption portion Ab1.

Therefore, the “adsorption portion located below the portion with greater warpage of the third substrate Wb [e.g., the first adsorption portion Ab1]” may absorb the bottom surface of the third substrate Wb with a stronger adsorption force than those of the “adsorption portion located below the portion with less warpage [e.g., the second adsorption portion Ab2 or the third adsorption portion Ab3]” in the third substrate Wb.

As described above, the adsorption force provided to each portion of the substrate Wa and Wb may be adjusted to increase in proportion to the degree of bending of each portion of the substrate Wa and Wb. Accordingly, as illustrated in Wa′ of FIG. 9 or Wb′ of FIG. 10, the bottom surfaces of the substrates Wa and Wb may be uniformly adsorbed and fixed to the hand body 910 despite differences in the degree of bending of each portion of the substrates Wa and Wb.

Meanwhile, the embodiment in which the adsorption module is disposed on the hand body 910 to detect the warpage of the substrates W, Wa, and Wb being transferred and adsorb and fix the substrates W, Wa, and Wb based on the detection has been described, but the present disclosure is not limited thereto.

In another embodiment, the adsorption module may be disposed on the support portion 412 to adsorb and fix the substrates W, Wa, and Wb. In this case, the transfer module 900 may detect the warpage state while the substrates W, Wa, and Wb are transferred. Thereafter, when the substrates W, Wa, and Wb are mounted and supported on the support portion 412 by the transfer module 900, the adsorption force of the adsorption portion Ab may be adjusted based on the detected warpage state to secure the substrates W, Wa, and Wb to the upper surface of the support portion 412. The specific method for controlling the plurality of adsorption portions Ab1, Ab2, and Ab3 based on the warpage detection result is the same as or similar to that described above, and therefore, a detailed description will be omitted.

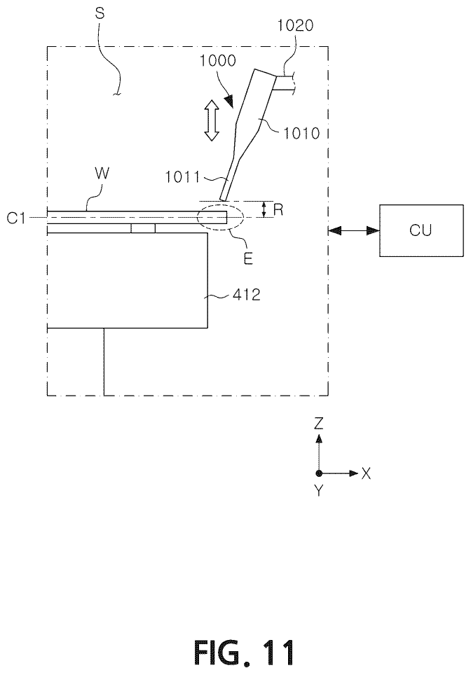

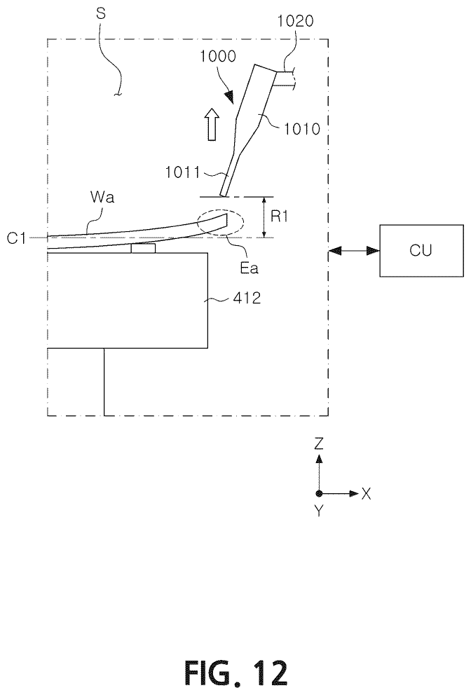

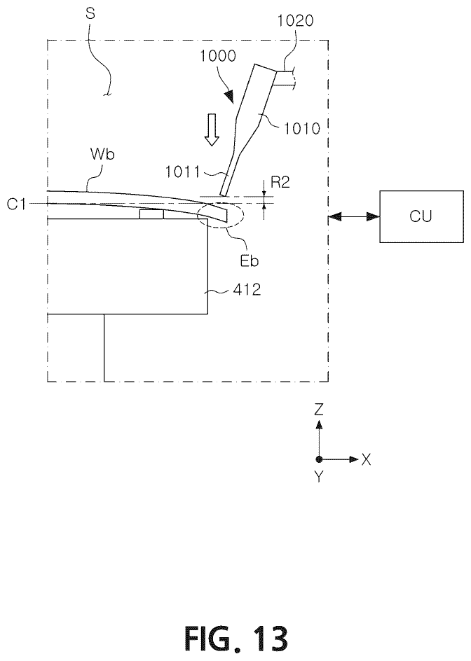

FIG. 11 is a cross-sectional view schematically illustrating an example of processing an edge portion of a substrate supported on a transfer module as viewed in direction I-I′ in FIG. 5. FIG. 12 is a cross-sectional view schematically illustrating another example of processing an edge portion of a substrate supported on a transfer module as viewed in direction I-I′ in FIG. 5. FIG. 13 is a cross-sectional view schematically illustrating another example of processing an edge portion of a substrate supported on a transfer module as viewed in direction I-I′ in FIG. 5.

Referring to FIGS. 11 to 13, the substrate processing apparatus 1 may further include a nozzle unit 1000.

During the substrate processing process, a photoresist film (not shown) may be formed on the substrate W by applying photoresist to the substrate W using the application module 401. After the photoresist film is formed, the nozzle unit 1000 may spray a processing liquid onto the substrate W to remove a portion of the photoresist film. More specifically, the nozzle unit 1000 may remove an unnecessary photoresist film formed on the edge portion E of the substrate W. In this manner, after the photoresist film on the edge portion E of the substrate W is removed, a heat treatment process, such as a baking process, may be performed.

The process of removing the photoresist film on the edge portion E of the substrate W described above may be performed after the substrate W is transferred into a processing space S of the processing chamber by the transfer module 900. Here, the transfer module 900 may transfer the substrate W so that the substrate W is supported on the support portion 412 disposed in the processing space S. The nozzle unit 1000 may remove the photoresist film on the edge portion E by applying a processing liquid to the substrate W supported by the support portion 412. Here, the nozzle unit 1000 may include a nozzle portion 1010, a supply line 1020, and a processing liquid supply portion (not shown).

The nozzle portion 1010 may be connected to the processing liquid supply portion via the supply line 1020. The nozzle portion 1010 may be disposed above the substrate W. Here, a nozzle tip 1011 of the nozzle portion 1010 may be disposed to face an edge portion E. In this state, the nozzle portion 1010 may apply the processing liquid supplied via the supply line 1020 to the edge portion E of the substrate W. During this process, the substrate W may rotate along with the rotation of the support portion 412. The processing liquid sprayed from the fixed nozzle portion 1010 is applied onto the edge portion E of the substrate W during rotation, thereby continuously removing the photoresist film of the edge portion E in a circumferential direction of the substrate W.

Here, the nozzle portion 1010 may apply the processing liquid while the nozzle tip 1011 is spaced apart from the substrate W by a predetermined distance. Hereinafter, for convenience of description, the distance by which the nozzle tip 1011 is spaced apart from the substrate W is defined as ‘space distances R, R1, and R2’. For example, the space distances R, R1, and R2 may be a linear distance in the vertical direction Z from the virtual center line C1 of the substrate W extending in the horizontal direction X.

In the above case, the controller CU may raise and lower the nozzle unit 1000 so that the edge portion E of the substrate W in which warpage has occurred does not come into contact with the nozzle tip 1011. Accordingly, by adjusting the height of the nozzle portion 1010, the nozzle tip 1011 may be maintained at a predetermined distance from the substrate W. Here, the controller CU may adjust the first separation distance R based on the warpage state of the substrate W. Hereinafter, when the first substrate W, which is a substrate in which warpage has not occurred, is supported on the support portion 412, the first separation distance R, which is a separation distance between the first substrate W and the nozzle tip 1011, is defined as a ‘reference distance R’.

For example, as illustrated in FIG. 12, based on the warpage detection result by the detection unit 920 performed during substrate transfer, the controller CU may determine that the second substrate Wa has a warpage in the first form. Here, since the second substrate Wa has a shape in which the degree of upward (+Z) bending gradually increases radially outward, an edge portion Ea of the second substrate Wa may protrude further upward than the edge portion E of the first substrate W.

In this case, the controller CU may raise the nozzle portion 1010 further upward (+Z) than in the case of the first substrate W, thereby preventing the nozzle tip 1011 from contacting the edge portion Ea of the second substrate Wa. Accordingly, the “second separation distance (R1)”, which is a distance by which the second substrate Wa is separated from the nozzle tip 1011, may increase, as compared to the aforementioned reference distance R.

As another example, as illustrated in FIG. 13, based on the warpage detection result by the detection unit 920 performed during substrate transfer, the controller CU may determine that the third substrate Wb has a warpage with the second shape. Here, since the third substrate Wb has a shape in which the degree of downward (−Z) bending gradually increases radially outward, the edge portion Eb of the third substrate Wb may protrude further downward than the edge portion E of the first substrate W.

In this case, the controller CU may lower the nozzle portion 1010 further downward (−Z) than in the case of the first substrate W, thereby preventing the nozzle tip 1011 from being further away from the edge portion Eb of the third substrate Wb than the reference distance R. This is to prevent the processing liquid from being applied or scattered to a portion other than the edge portion E due to the nozzle tip 1011 being too far from the edge portion Eb. Accordingly, the ‘third separation distance R2’, which is the distance between the third substrate Wb and the nozzle tip 1011, may be reduced from the aforementioned reference distance R.

As described above, the controller CU may prevent the nozzle tip 1011 from contacting the edge portions Ea and Eb or from being excessively separated from the edge portions Ea and Eb by adjusting the height of the nozzle portion 1010 based on the shape and degree of bending of the substrate Wa and Wb. Accordingly, even when various warpages occur on the substrate Wa and Wb, the nozzle tip 1011 may be controlled to be disposed within an appropriate distance range from the edge portions Ea and Eb. As a result, the photoresist film on the edge portions E, Ea, and Eb may be effectively removed in response to the warpage shape occurring on the substrates W, Wa, and Wb.

As described above, the transfer module 900 and the substrate processing apparatus 1 including the transfer module 900 according to the embodiments of the present disclosure may shorten the substrate processing process time since warpage detection is performed while the substrates W, Wa, and Wb are being transferred, and thus, there is no need for a separate time for warpage detection. Furthermore, since the detection unit 920 is installed directly on the hand body 910, a separate installation space is unnecessary, thereby improving space efficiency within the substrate processing apparatus 1.

Furthermore, the adsorption force provided to each portion of the bottom surface of the substrate W is adjusted to be different according to various warpage shapes that may occur on the substrate W, and thus, the bottom surface of the substrate W may be uniformly and tightly secured, even after the substrate W is mounted on the support portion 412, as well as being transferred by the hand body 910. Furthermore, even a subsequent process, such as EBR, performed after the substrate transfer is completed, may be appropriately responded to the warpage shape of the substrate W, thereby improving the efficiency of the subsequent process.

The transfer module and the substrate processing apparatus including the transfer module according to embodiments of the present disclosure may shorten the process time for substrate processing because warpage detection is performed during substrate transfer. Furthermore, since the warpage detection unit is installed directly on the hand body, no separate installation space is required, thereby improving the space efficiency of the substrate processing apparatus.

Furthermore, since adsorption forces are adjusted to be provided to each portion of the bottom surface of the substrate to accommodate the various warpage types that may occur on the substrate, the bottom surface of the substrate may be uniformly and tightly secured throughout, not only during transfer by the hand body but also after placement on the support portion of the substrate. Furthermore, subsequent processes, such as EBR, performed after substrate transfer, may be appropriately adjusted to accommodate the warpage type of the substrate, thereby improving the efficiency of subsequent processes.

In the above examples, the substrate processing apparatus of the present disclosure has been described as an embodiment applied to a photo process, but the present disclosure is not limited thereto and it is obvious to those skilled in the art that the present disclosure may be applied to various processes, such as a substrate etching process, a test process, and a packaging process, and this will also fall within the scope of the present disclosure.

What is claimed is:

1. A transfer module comprising:
a hand body supporting and handling a substrate;
a detection unit including a light emitting portion disposed on a first side of the hand body and emitting light in one direction and a light receiving portion disposed on a second side of the hand body and receiving the light and detecting warpage of the substrate; and
a controller determining a warpage state of the substrate based on a detection result of the warpage.

2. The transfer module of claim 1, further comprising:
a first transfer unit coupled to the hand body and raising and lowering the hand body in a vertical direction; and
a second transfer unit coupled to the first transfer unit and moving the hand body in a horizontal direction.

3. The transfer module of claim 1, wherein, when the substrate is supported on the hand body, the light emitting portion and the light receiving portion are arranged opposite to each other in one direction with the substrate interposed therebetween.

4. The transfer module of claim 1, wherein the light receiving portion includes a light receiving region in which the light is incident, the light receiving region is divided into a plurality of regions, and the controller determines the warpage state based on an amount of incident light detected for each region of the light receiving region.

5. The transfer module of claim 4, wherein the controller determines the warpage state of the substrate by comparing the amount of incident light detected in each region of the light receiving region with a reference value.

6. The transfer module of claim 5, wherein the light receiving portion includes a first region disposed above the substrate supported on the hand body and a second region disposed below the substrate.

7. The transfer module of claim 6, wherein the controller determines a direction and degree of bending of the substrate by comparing the amount of incident light detected in the first region with a first reference value or comparing the amount of incident light detected in the second region with a second reference value.

8. The transfer module of claim 7, wherein the controller determines that the substrate is at least partially bended upward when the amount of incident light detected in the first region is less than the first reference value and determines that the substrate is at least partially bended downward if the amount of incident light detected in the second region is less than the second reference value.

9. A substrate processing apparatus comprising:
a transfer module including a hand body supporting and handling a substrate and a detection unit including a light emitting portion disposed on a first side of the hand body and emitting light in one direction and a light receiving portion disposed on a second side of the hand body and receiving the light and detecting warpage of the substrate;
an adsorption module disposed on the hand body and including a plurality of adsorption portions adsorbing and fixing a bottom surface of the substrate; and
a controller determining a warpage state of the substrate based on a detection result of the warpage and controlling the adsorption module.

10. The substrate processing apparatus of claim 9, wherein, when the substrate is supported on the hand body, the light emitting portion and the light receiving portion are arranged opposite to each other in one direction with the substrate interposed therebetween.

11. The substrate processing apparatus of claim 9, wherein the light receiving portion includes a light receiving region in which the light is incident, the light receiving region is divided into a plurality of regions, and the controller determines the warpage state based on an amount of incident light detected for each region of the light receiving region.

12. The substrate processing apparatus of claim 11, wherein the controller determines the warpage state of the substrate by comparing the amount of incident light detected in each region of the light receiving region with a reference value.

13. The substrate processing apparatus of claim 12, wherein the light receiving portion includes a first region disposed above the substrate supported on the hand body and a second region disposed below the substrate.

14. The substrate processing apparatus of claim 13, wherein the controller determines a direction and degree of bending of the substrate by comparing the amount of incident light detected in the first region with a first reference value or comparing the amount of incident light detected in the second region with a second reference value.

15. The substrate processing apparatus of claim 14, wherein the controller determines that the substrate is at least partially bended upward when the amount of incident light detected in the first region is less than the first reference value and determines that the substrate is at least partially bended downward when the amount of incident light detected in the second region is less than the second reference value.

16. The substrate processing apparatus of claim 14, wherein the controller determines that the degree of the upward or downward bending of the substrate is greater as a detection value of the amount of incident light in the first region and a detection value of the amount of incident light in the second region decrease.

17. The substrate processing apparatus of claim 9, wherein the controller controls adsorption force of the adsorption portion to increase or decrease in proportion to a degree of bending of the substrate.

18. The substrate processing apparatus of claim 9, further comprising:
a nozzle unit including a nozzle portion spraying a processing liquid onto an edge portion of the substrate and applying the processing liquid through the nozzle portion to remove a photoresist film on the edge portion,
wherein the controller adjusts a position of the nozzle portion based on the warpage state.

19. The substrate processing apparatus of claim 18, wherein the controller adjusts a separation distance between a nozzle tip of the nozzle portion and the substrate to a predetermined distance range by raising or lowering the nozzle portion in proportion to the degree of bending of the substrate.

20. A substrate processing apparatus comprising:
a processing chamber having a processing space provided therein;
a transfer module including a hand body disposed on one side of the processing chamber to transfer a substrate to the processing space and supporting and handling the substrate and a detection unit including a light emitting portion disposed on a first side of the hand body and emitting light in one direction and a light receiving portion disposed on a second side of the hand body and receiving the light, wherein the light emitting portion and the light receiving portion are disposed opposite to each other in the one direction with the substrate supported on the hand body interposed therebetween and the detection unit detects a warpage of the substrate;
an adsorption module disposed on the hand body and including a plurality of adsorption portions adsorbing and fixing a bottom surface of the substrate; and
a controller determining a warpage state of the substrate based on a detection result of the warpage and controlling the adsorption module,
wherein the light receiving portion includes a light receiving region in which the light is incident, the light receiving region is divided into a plurality of regions, including first region disposed above the substrate supported by the hand body and a second region disposed below the substrate, based on the substrate, and
the controller determines a warpage state including a direction and degree of bending of the substrate by comparing an amount of incident light detected in the first region with a first reference value and comparing an amount of incident light detected in the second region with a second reference value,
the controller determines that the substrate is at least partially bended upward when the amount of incident light detected in the first region is less than the first reference value and determines that the substrate is at least partially bended downward if the amount of incident light detected in the second region is less than the second reference value, and
the controller determines that the degree of the upward or downward bending of the substrate is greater as a detection value of the amount of incident light in the first region and a detection value of the amount of incident light in the second region decrease.
